(19) United States
(12) Patent Application Publication
(10) Pub. No.: US 2006/0148228 A1
(43) Pub. Date: Jul. 6, 2006

(54) Method for forming salicide layer in semiconductor device

(76) Inventor: Ki Wan Bang, Cheongju-si (KR)

Correspondence Address: MCKENNA LONG & ALDRIDGE LLP;Song K. Jung, 1900 K Street, N.W., Washington, DC, 20006, US

(21) Appl. No.: 11/320,779

(22) Filed: Dec. 30, 2005

(30) Foreign Application Priority Data
Dec. 31, 2004 (KR) 2004-117851

(51) Int. Cl. H01L 21/4763; H01L 21/3205

(52) U.S. Cl. 438/592

(57) ABSTRACT

A method for forming a silicide layer in a semiconductor device selectively forms a self-aligned layer of silicide in a salicidation area only, without having to use a salicide blocking material such as an oxide or a nitride. The method includes steps of defining a salicidation area and a non-salicidation area on a substrate; depositing a salicide forming metal on the substrate after forming a gate electrode and a source-drain diffusion region; forming a photoresist pattern on the salicidation area; removing the salicide forming metal from the non-salicidation area; removing the photoresist pattern; and annealing the salicide forming metal.

### CROSS-REFERENCE TO RELATED APPLICATION

This application claims the benefit of Korean Patent Application No. 10-2004-0117851, filed on Dec. 31, 2004, which is hereby incorporated by reference as if fully set forth herein.

### BACKGROUND OF THE INVENTION

1. Field of the Invention

The present invention relates to a semiconductor device, and more particularly, to a method for forming a silicide layer in a semiconductor device.

2. Discussion of the Related Art

In semiconductor devices such as MOSFETs, the minimum surface resistance of a thin polysilicon gate or a shallow source-drain diffusion region is about 10-20 ohms/square, which results in an inefficient interconnection and limits the speed of a very large scale integration (VLSI) circuit. To reduce effective surface resistance of the interconnection, a silicide having a low resistivity is formed on a silicon surface, for example the upper surface, of a polysilicon gate or source-drain region. Silicide is a compound of silicon and one of various noble metals or high-temperature-resistant metals, for example, group XIII metals such as cobalt, group IV metals such as titanium, and metals having a high melting point such as tungsten. Among these, cobalt and titanium, which respectively form CoSi₂ and TiSi₂ by combining with the silicon, are widely used.

A metallization process performed for manufacturing a semiconductor device includes a process of forming a self-aligned layer of silicide, referred to as a salicide process, which simultaneously forms an electrical contact on the gate and on the source-drain. Benefits of salicidation include the removal of a parasitic capacitance that may be generated between the gate and the source-drain and a reduction in the resistivity of the source-drain. Salicidation is typically carried out after formation of the gate and the source-drain, whereby a field oxide region such as shallow-trench isolation region is first formed for isolating an active area of a transistor, a polysilicon gate electrode is formed in the active area, ion implantation forms a source-drain diffusion region which is then annealed, and sidewall spacers of oxide are formed by a reactive ion etching of an oxide layer by chemical vapor deposition.

FIGS. 1A-1D illustrate a conventional salicide process. Salicide layer formation is carried out after a gate oxide 15, a polysilicon gate electrode 16, a source-drain diffusion region 12, and an oxide spacer 18 are formed with respect to a field region 14. The gate electrode and the source-drain diffusion region formed on a substrate 10 include a salicidation area where salicide is formed and a non-salicidation area where salicide is not formed, i.e., the formation of salicide is blocked. The gate and the source-drain diffusion region independently exist in the non-salicidation area. FIGS. 1A-1D show the process with respect to a shallow-trench isolation region as the field region, and the gate of such a region is an example of the non-salicidation area.

As shown in FIG. 1A, when the salicidation and non-salicidation areas are determined according to a specific wafer layout, a salicide blocking material 20 such as a silicon nitride or a silicon oxide is formed on the whole surface of the wafer. The salicide blocking material 20 can be used to inhibit a reaction between a silicon and a metal (e.g., cobalt or titanium) in the non-salicidation area.

As shown in FIG. 1B, after coating the entire surface of the wafer with photoresist, a photoresist pattern 22 is formed by photolithography. The photoresist of the salicidation area is removed to leave only the photoresist on the non-salicidation area.

As shown in FIG. 1C, the salicide blocking material 20 is removed from the salicidation area by dry etching or wet etching.

As shown in FIG. 1D, the photoresist pattern 22 is removed from the non-salicidation area. A salicide forming metal 24, such as titanium or cobalt, is then deposited on the entire surface of the wafer, including both the salicidation area and the non-salicidation area. Next, an annealing process is performed to the entire substrate (wafer) to thereby form a salicide layer (not shown) on upper surfaces of each of the gate electrode 16 and the source-drain diffusion region 12 simultaneously. During annealing, salicide is formed in areas where the metal comes in contact with the silicon and the polysilicon and is not formed in other areas. There is no salicide formed in the non-salicidation area since the salicide blocking material 20 inhibits the necessary reaction, i.e., between the salicide forming metal 24 and the silicon of either the gate electrode 16 or the source-drain diffusion region 12.

After the salicide is formed, i.e., in the salicidation area on the gate electrode 16 and the source-drain diffusion region 12, the unreacted metal is removed by selective etching to obtain a self-aligned silicide layer, i.e., a salicide layer. The salicide layer can be seen in FIG. 2, which shows a salicide formation 26a in a polysilicon 16 and a salicide formation 26b in a silicon of the source-drain diffusion region 12.

In the aforementioned salicide forming method, the salicide blocking material 20 formed in the salicidation area must be removed by dry etching or wet etching, as a separate process step. Furthermore, in the case of dry etching, exposed silicon surfaces may be damaged by plasma, and in the case of wet etching, the undercutting 28 of the oxide spacer may occur, as shown in FIG. 2.

### SUMMARY OF THE INVENTION

Accordingly, the present invention is directed to a method for forming a silicide layer in a semiconductor device that substantially obviates one or more disclosed or undisclosed problems or issues that may be due to limitations and disadvantages of the related art.

A method in accordance with an exemplary embodiment of the present invention forms a silicide layer in a semiconductor device in which a salicide can be selectively formed only in a salicidation area without the use of a salicide blocking material.

The present invention may provide a method for forming a silicide layer in a semiconductor device, which simplifies the manufacture of an integrated circuit by reducing processing steps.

The present invention may provide a method for forming a silicide layer in a semiconductor device that avoids dry etching, thereby preventing plasma damage to exposed silicon surfaces, and avoids wet etching, thereby preventing an undercutting of an oxide spacer.

Additional advantages, objects, and features of the invention will be set forth in part in the description which follows and in part will become apparent to those having ordinary skill in the art upon examination of the following. These and other advantages of the invention may be realized and attained by the structure particularly pointed out in the written description and claims hereof as well as the appended drawings.

To achieve these and other advantages in accordance with the invention, as embodied and broadly described herein, a method for forming a silicide layer in a semiconductor device includes defining a salicidation area and a non-salicidation area on a substrate; depositing a salicide forming metal on the substrate after forming a gate electrode and a source-drain diffusion region; forming a photoresist pattern on the salicidation area; removing the salicide forming metal from the non-salicidation area; removing the photoresist pattern; and annealing the salicide forming metal.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate embodiments of the invention and, together with the description, serve to explain the principle of the invention. In the drawings:

FIGS. 1A-1D are cross-sectional views of a semiconductor device, including a gate electrode and a source-drain diffusion region, respectively illustrating sequential process steps of a conventional salicide forming method using a salicide blocking material;

FIG. 2 is a photograph of a gate electrode and a source-drain diffusion region formed as in the method of FIGS. 1A-1D showing an undercutting due to wet etching; and

FIGS. 3A-3D are cross-sectional views of a semiconductor device, including a gate electrode and a source-drain diffusion region, respectively illustrating sequential process steps of an exemplary method for forming a salicide layer according to the present invention.

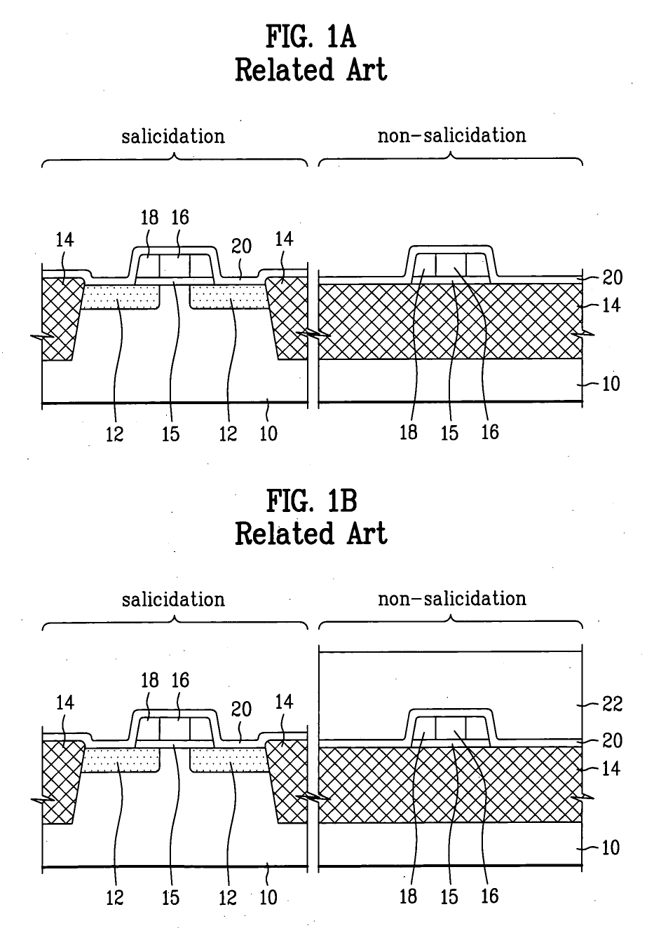

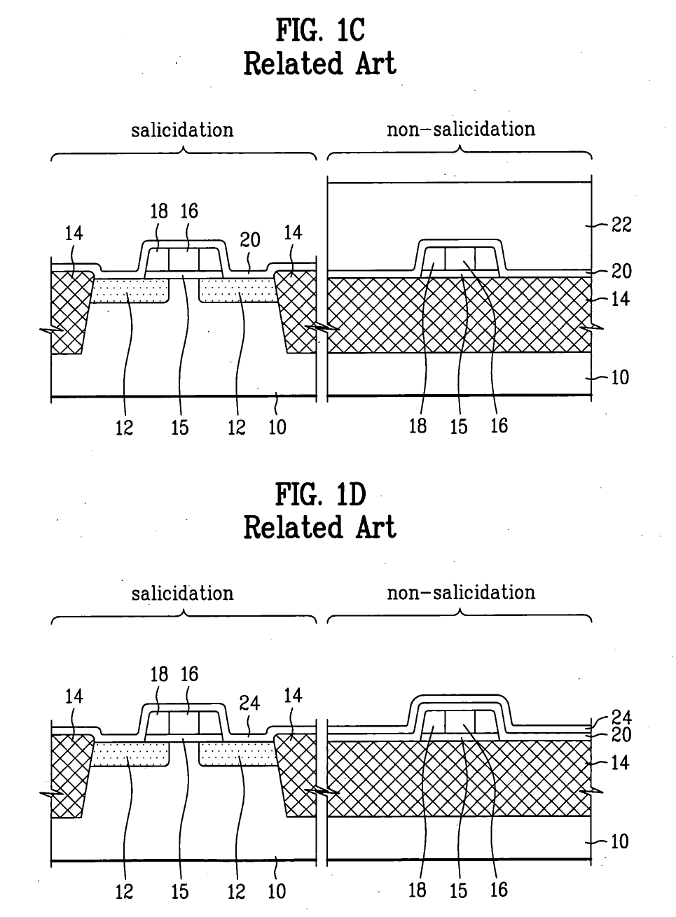

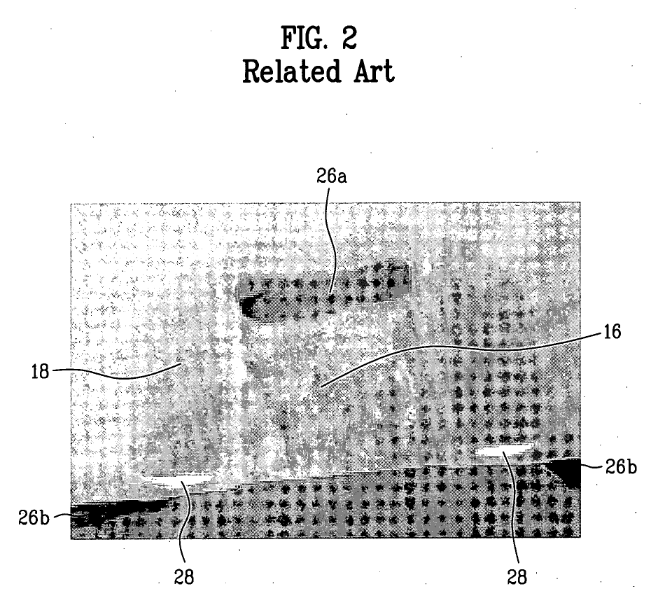

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

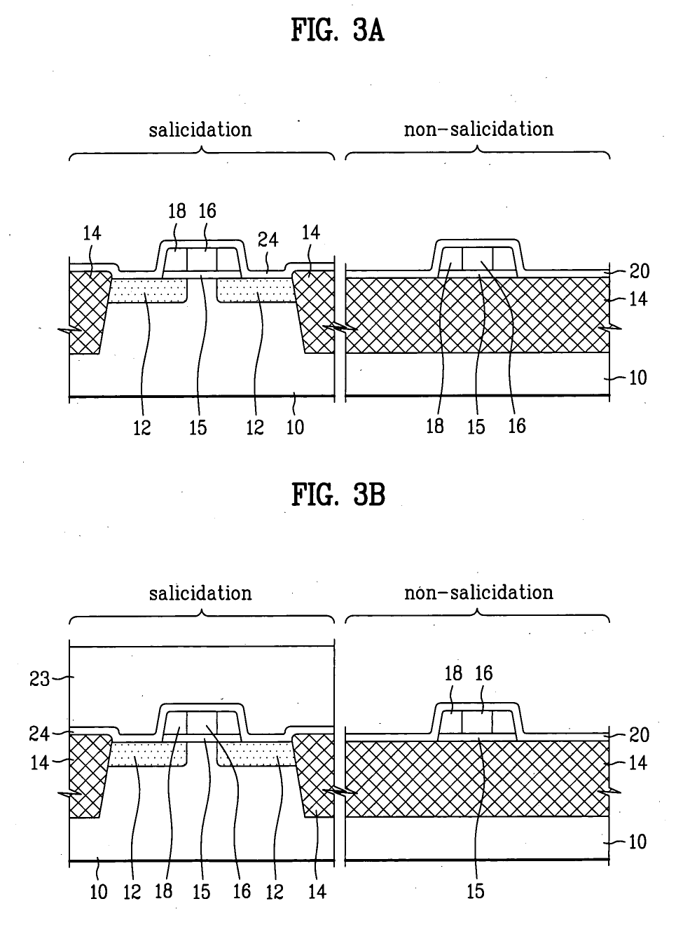

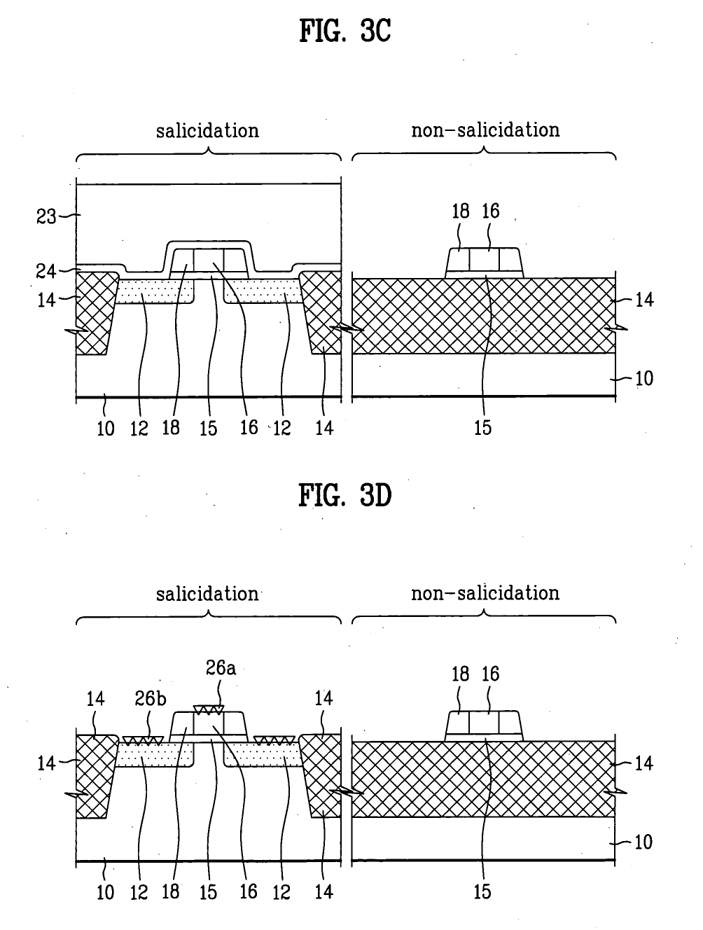

FIGS. 3A-3D respectively show steps of a salicide forming method according to one embodiment of the present invention, which simultaneously forms an electrical contact on top of a gate electrode and a source-drain diffusion region and carried out after formation of the gate electrode and the source-drain diffusion region on a semiconductor substrate.

As shown in FIG. 3A, a gate electrode 16, a source-drain diffusion region 12, and an oxide layer spacer 18 are formed on a substrate 10. A salicide forming metal 24 such as cobalt or titanium is then deposited on the entire surface of the substrate 10. The salicide forming metal 24 can be deposited over the whole wafer, including a salicidation area and a non-salicidation area.

As shown in FIG. 3B, the whole surface of the wafer, including the salicidation and non-salicidation areas, can be coated with a photoresist, which is removed from the non-salicidation area by photolithography. Thus, a photoresist pattern 23 remains on the salicidation area.

Referring to FIG. 3C, as a portion of the metal layer 24 deposited in a previous step is exposed in the non-salicidation area by the photolithography process, the exposed metal layer is removed by dry etching or wet etching.

Referring to FIG. 3D, with the partial removal of the metal of the metal layer 24 from the non-salicidation area, the photoresist pattern 23 on the salicidation area is also removed. An annealing process for reacting the salicide forming metal 24 with the underlying a silicon surface is then carried out. During the annealing process, the salicide is formed only in areas where the metal layer 24 comes in contact with the silicon and a polysilicon, i.e., in the salicidation area. After the annealing process, the remaining un-reacted metal layer 24 is removed by a selective etching to obtain a self-aligned silicide (salicide) layer on the gate 16 and on the source-drain diffusion region 12. The salicide layer thus comprises a salicide formation 26a on the polysilicon 26 and a salicide formation 26b on the silicon of the source-drain diffusion region 12.

Accordingly, in manufacturing an integrated circuit of a MOS transistor, a salicide layer can be selectively formed only in a salicidation area without having to use a salicide blocking material to block the reaction between a metal and a silicon, i.e. in a non-salicidation area using a salicide blocking material such as a silicon nitride layer or a silicon oxide layer. Since the salicide blocking material may not used in the present invention, the steps of depositing and removing the salicide blocking material can be eliminated, thereby simplifying the overall process. In contrast to the use of the salicide blocking material such as the silicon nitride layer or the silicon oxide layer, the present invention can prevent the problem of damaging a semiconductor device in an etching process for removing the salicide blocking material.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A method for forming a silicide layer in a semiconductor device, comprising:
defining a salicidation area and a non-salicidation area on a substrate;
depositing a salicide forming metal on the substrate after forming a gate electrode and a source-drain diffusion region;
forming a photoresist pattern on the salicidation area;
removing the salicide forming metal from the non-salicidation area;
removing the photoresist pattern; and
annealing the salicide forming metal.

2. The method according to claim 1, wherein the photoresist pattern is formed by coating an entire surface of the substrate with a layer of photoresist and removing the photoresist from the non-salicidation area.

3. The method according to claim 2, wherein the photoresist layer is formed on the salicide forming metal.

4. The method according to claim 1, wherein the salicide forming metal is cobalt.

5. The method according to claim 1, wherein the salicide forming metal is titanium.

6. The method according to claim 1, wherein said annealing reacts the salicide forming metal with a surface silicon of the gate electrode and the source-drain diffusion region.

7. The method according to claim 6, further comprising removing unreacted metal by a selective etching process.

8. The method according to claim 1, further comprising forming a spacer on lateral walls of the gate electrode to electrically isolate the gate electrode and the source-drain diffusion region.

9. The semiconductor device manufactured in accordance with the method of claim 1.
